(19) United States
(12) Patent Application Publication
(10) Pub. No.: US 2015/0240362 A1
(43) Pub. Date: Aug. 27, 2015

(54) APPARATUS FOR DENSIFYING CARBON/CARBON COMPOSITE MATERIAL

(71) Applicant: DACC CARBON, JEONJU-SI (KR)

(72) Inventors: Woo Chul CHOI, Gimhae-si (KR); Jong Hyun PARK, Jeonju (KR); Chae Wook CHO, Daejeon (KR); Cheol Su YUN, Jeonju-si (KR)

(21) Appl. No.: 14/580,835

(22) Filed: Dec. 23, 2014

(30) Foreign Application Priority Data
Feb. 26, 2014 (KR) 10-2014-0022853

(51) Int. Cl. C23C 16/46; C23C 16/22

(52) U.S. Cl. CPC C23C 16/46; C23C 16/22

(57) ABSTRACT

A densifying apparatus including: a reaction chamber; a fixed heater is disposed close to the inner wall of the reaction chamber and generating heat; a detachable heater detachably coupled to the reaction chamber and generating heat; and a gas supply unit supplying a gas into the reaction chamber. It is possible to minimize energy consumption when densifying a small amount of preforms or a large amount of preforms and uniformly densify disc preforms having the shape of a thick ring. Further, it is possible to reduce time to density those preforms.

### CROSS-REFERENCE TO RELATED APPLICATIONS

This application claims the priority of Korean Patent Application No. 10-2014-0022853 filed on Feb. 26, 2014, in the Korean Intellectual Property Office, the disclosure of which is incorporated herein by reference.

### BACKGROUND OF THE INVENTION

1. Field of the Invention

The present invention relates to a densifying apparatus.

2. Description of the Related Art

In general, there are, as heat resistant composite materials, a carbon reinforcing silicon carbide composite material (C_{f}/SiC), a silicon carbide fiber reinforcing silicon carbide composite material (SiC_{f}/SiC), and a carbon fiber reinforcing carbon composite material (C_{f}/C).

A method of manufacturing a heat resistant composite material is to form a preform by weaving a carbon fiber (Cf) or a silicon carbide fiber (SiCf), and fill silicon carbide (SiC) or carbon (C) that is a component of a matrix in between the fibers in the preform (hereafter, referred to as ‘densifying’).

As methods of densifying a preform, there are chemical vapor infiltration (CVI), polymer infiltration pyrolysis (PIP), and liquid silicon infiltration (LSI).

When a heat resistant composite material is formed by liquid silicon infiltration, it is possible to reduce the manufacturing time and achieve a dense heat resistant composite material, as compared with using chemical vapor infiltration or polymer infiltration pyrolysis. However, the content of metal silicon in the heat resistant composite material increases, as compared with making a heat resistant material using chemical vapor infiltration or polymer infiltration pyrolysis, so heat resistance and durability are deteriorated.

Chemical vapor infiltration, a typical densifying method, produces silicon carbide that is a component of a matrix, by putting methyl trichloro silane (MTS) or mono methyl silane (MMS) into a preform and then reacting them under appropriate conditions. Equipment for chemical vapor infiltration stacks a plurality of preforms in a reaction chamber and then supplies a precursor, which forms a matrix, in a gas state into the reaction chamber. The temperature and pressure inside the reaction chamber are adjusted so that the gas supplied in the reaction chamber infiltrates into the preform and is deposited.

Equipment for densifying a preform using chemical vapor infiltration has been disclosed in U.S. Pat. No. 5,904,957 (registered on May 18, 1999) (hereafter, referred to as a prior art).

According to the prior art, a plurality of preforms are stacked in a cylindrical core heater 9 of a reaction chamber, the internal temperature of the reaction chamber is increased by the core heater, and then a reaction gas is injected into the reaction chamber, thereby densifying the preforms.

However, the prior art is suitable for equipment for densifying a plurality of preforms at a time, but the core heater should be operated to maintain the internal temperature of the reaction chamber at 700 to 1300 degrees, even if a small amount of preforms are densified, so a loss of power is too much and it take long time to densify a small amount of preforms. In particular, when preforms are a small amount of ring-shaped thick discs, it takes too much time to densify the small amount of preforms, and a matrix is formed to a predetermined depth from the surfaces of the preforms and a gas cannot infiltrate to the center in the preforms, so the preforms cannot be filled with the matrix. As a matrix is not uniformly formed in a preform, the heat resistance and mechanical properties of a heat resistant material made of the preform are poor.

On the other hand, small-sized densifying equipment is expensive and a large cost is required.

### SUMMARY OF THE INVENTION

An aspect of the present invention provides a densifying apparatus that minimize energy consumption when densifying a small amount of preforms or a large amount of preforms.

Another aspect of the present invention provides a densifying apparatus that not only uniformly densifies thick ring-shaped disc preforms, but reduce time taken to densify the preforms.

According to an aspect of the present invention, there is provided a densifying apparatus including: a reaction chamber; a fixed heater is disposed close to the inner wall of the reaction chamber and generating heat; a detachable heater detachably coupled to the reaction chamber and generating heat; and a gas supply unit supplying a gas into the reaction chamber.

The reaction chamber may be formed in the shape of a cylinder having an internal space, with the top and the bottom closed, and is radially separated in to three parts, the three parts may be a center body that is the middle part, a left door part hinged to a first side of the center body and opening/closing the first side of the center body, and a right door part hinged to a second side of the center body and opening/closing the other side of the center body.

Contact plates having uniform width and thickness may be disposed outside the edges of both opening sides of the center body, a contact plate facing one of the contact plates of the center body may be disposed outside the edge of the left door part, and a contact plate facing the other contact plate of the center body may be disposed outside the edge of the right door part.

The fixed heater may include a cylindrical heating unit disposed in the reaction chamber, an upper ring-shaped heating unit having a circular disc shape with the center bored and disposed on the top of the cylindrical heating unit, and a lower ring-shaped heating unit having a circular disc shape with the center bored and disposed under the cylindrical heating unit.

The detachable heater may be attached/detached longitudinally vertically to/from the reaction chamber.

The detachable heater may include a heater body formed in the shape of a circular rod, a lower coupler disposed at the lower end of the heating body and attached/detached to/from the bottom of the reaction chamber, an upper coupler disposed at the upper end of the heating body and attached/detached to/from the top of the reaction chamber.

A lower support may be formed at the lower portion of the heating body and support a ring-shaped preform, and an upper support may be formed at the upper portion of the heating body and support a preform fitted on the heating body.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a front view illustrating a densifying apparatus according to an embodiment of the present invention;

FIG. 2 is a plan view illustrating the densifying apparatus according to an embodiment of the present invention;

FIG. 3 is a front cross-sectional view illustrating a door of the densifying apparatus according to an embodiment of the present invention;

FIG. 4 is a front cross-sectional view illustrating preforms stacked in a reaction chamber, with a detachable heater separated from the densifying apparatus according to the present invention;

FIG. 5 is a front view illustrating preforms stacked on the detachable heater of the densifying apparatus according to an embodiment of the present invention; and

FIG. 6 is a front cross-sectional view illustrating preforms stacked on the detachable heater and loaded in a reaction chamber of the densifying apparatus according to the present invention.

### DETAILED DESCRIPTION OF THE PREFERRED EMBODIMENT

Exemplary embodiments of the present invention will now be described in detail with reference to the accompanying drawings.

Hereinafter, a densifying apparatus according to an embodiment of the present invention will be described with reference to the accompanying drawings.

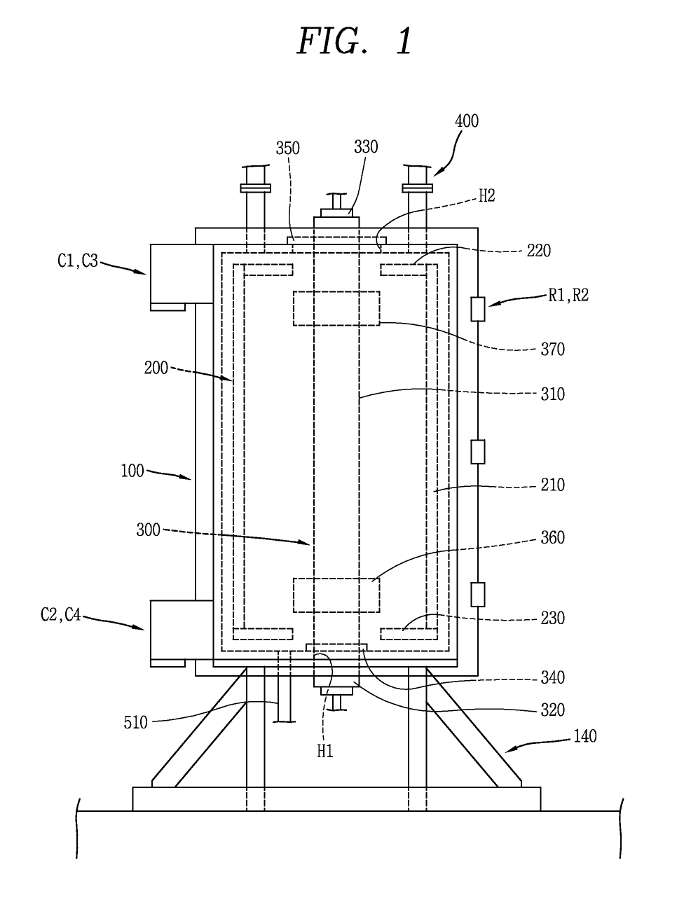

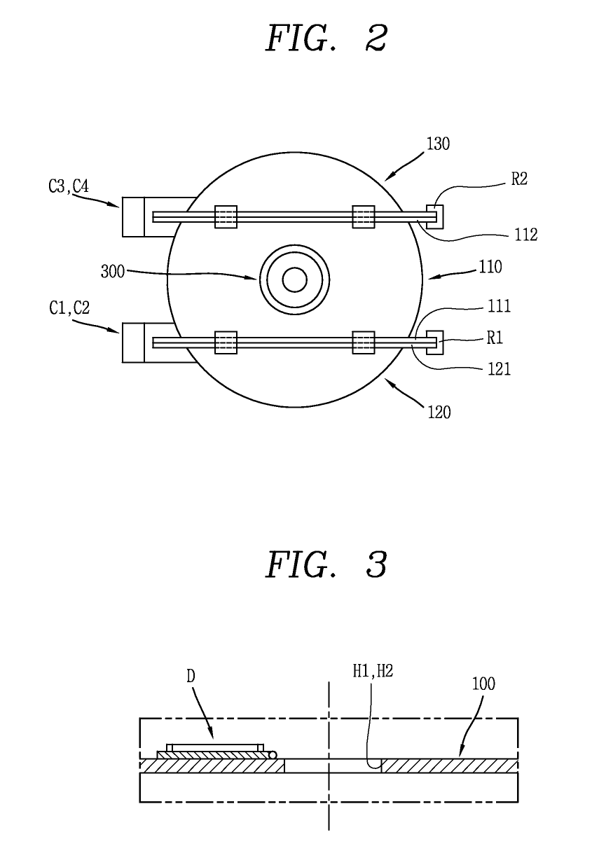

FIG. 1 is a front view illustrating a densifying apparatus according to an embodiment of the present invention. FIG. 2 is a plan view illustrating the densifying apparatus according to an embodiment of the present invention.

As illustrated in FIGS. 1 and 2, a densifying apparatus according to an embodiment of the present invention includes a reaction chamber 100, a fixed heater 200, a detachable heater 300, and a gas supply unit 400.

The reaction chamber 100 may be a cylinder having an internal space, with the top and the bottom closed. For example, the reaction chamber 100 is radially divided into three parts. That is, the reaction chamber is composed of a center body 110 that is the middle part and left and right door parts 120 and 130 at both sides of the center body 110. Both sides of the center body 110 are open. The left door part 120 is hinged to a first side of the center body 110 and opens/closes the first side of the center body 110. The right door part 130 is hinged to a second side of the center body 110 and opens/closes the second side of the center body 110. Hinge assemblies C1 and C2 are coupled to the upper portions and the lower portions of the center body 110 and the left door part 120, and hinge assemblies C3 and C4 are coupled to the upper portions and the lower portions of the center body 110 and the left door part 130. Contact plates 111 and 112 having uniform width and thickness may be disposed outside the edges of both opening sides of the center body 110. A contact plate 121 facing the contact plate 111 of the center body 110 may be disposed outside the edge of the left door part 120 and a contact plate 131 facing the contact plate 112 of the center body 110 may be disposed outside the edge of the right door part 130. Rocking units R1 are coupled to the contact plate 111 of the center body 110 and the contact plate 121 of the left door part 120, so the contact plate 111 of the center body 110 and the contact plate 121 of the left door part 120 are fixed in close contact with each other or separated from each other by the rocking units R1. Further, rocking units R2 are coupled to the contact plate 112 of the center body 110 and the contact plate 131 of the right door part 130, so the contact plate 112 of the center body 110 and the contact plate 131 of the left door part 130 are fixed in close contact with each other or separated from each other by the rocking units R2. A large sealing effect is achieved by surface contact between the contact plates 111 and 112 of the center body 110 and the contact plates 121 and 131 of the left and right door parts 130.

A support frame 140 is disposed under the reaction chamber 100. That is, the bottom of the reaction chamber 100 is supported on the support frame 140.

The fixed heater 200 is disposed close to the inner wall of the reaction chamber 100 and generates heat using power that is applied. For example, the fixed heater 200 includes a cylindrical heating unit 210 disposed in the reaction chamber 100, an upper ring-shaped heating unit 220 having a circular disc shape with the center bored and disposed on the top of the cylindrical heating unit 210, and a lower ring-shaped heating unit 230 having a circular disc shape with the center bored and disposed under the cylindrical heating unit 210. When the reaction chamber 100 is composed of three parts, the fixed heater 200 is also divided into three parts, corresponding to the reaction chamber 100.

The detachable heater 300 is detachably coupled to the reaction chamber 100 and generates heat using power that is applied. The detachable heater 300 may be attached/detached longitudinally vertically to/from the reaction chamber 100. For example, the detachable heater 300 includes a heater body 310 formed in the shape of a circular rod, a lower terminal at the lower portion of the heating body 310, and an upper terminal 330 at the upper portion of the heating body 310. A lower coupler 340 and an upper coupler 350 that are attached/detached to/from the bottom and the top of the reaction chamber 100 may be disposed on the bottom and the top of the heating body 310, respectively. The heating body 310 may have a uniform outer diameter. The heating body 310 may be made of graphite.

For example, the lower coupler 340 is formed in the shape of a disc being larger than the outer diameter of the heating body 310 and having a predetermined thickness, and a hole H1 that is larger than the outer diameter of the heating body 310 and smaller than the outer diameter of the lower coupler 340 is formed through the bottom of the reaction chamber 100 where the lower coupler 340 is disposed. For example, the upper coupler 350 is formed in the shape of a disc being larger than the outer diameter of the heating body 310 and having a predetermined thickness, and a hole H2 that is larger than the outer diameter of the heating body 310 and smaller than the outer diameter of the upper coupler 350 is formed through the top of the reaction chamber 100 where the upper coupler 350 is disposed.

Doors D that close the portions where the detachable heater 300 is attached/detached, that is, the holes H1 and H2 when the detachable heater 300 is separated, as illustrated in FIG. 3, are formed on the top and the bottom, respectively, of the reaction chamber 100.

The detachable heater 300 may be attached/detached horizontally. Accordingly, the lower coupler 340 and the upper coupler 350 may be implemented in various shapes.

A lower support 360 that supports preforms is formed at the lower portion of the heating body 310 and an upper support 370 that supports preforms mounted on the heating body 310 is formed at the upper portion of the heating body 310. The lower support 360 and the upper support 370 maybe formed in the shape of a ring having uniform width and height. Preforms mounted on the heating body 310 are formed in the shape of a ring with a hole therein, so the preforms are mounted on the heating body 310 with the heating body 310 inserted in the holes of the preforms.

The power supplier (not illustrated) is provided to selectively or simultaneously supply power to the fixed heater 200 and the detachable heater 300.

The gas supply unit 400 supplies a gas into the reaction chamber 100. The gas supply unit 400 includes a gas intake pipe 410 connected to the reaction chamber 100 to communicate with the inside of the reaction chamber 100, a pipe system (not illustrated) connected to the gas intake pipe 410, a plurality of gas storages (not illustrated) connected to the pipe system, a gas mixing container (not illustrated) connected to the pipe system, and flow control units (not illustrated) disposed in the pipe system. The gas intake pipes 410 may be a plurality of pieces and the plurality of gas intake pipes 410 may be connected to the top of the reaction chamber 100, with regular intervals. A gas preheating unit (not illustrated) that preheats a gas may be disposed in the pipe system.

A gas exhaust pipe 510 through which a gas is discharge is connected to the bottom of the reaction chamber 100.

The operation and effects of the densifying apparatus according to an embodiment of the present invention is described hereafter.

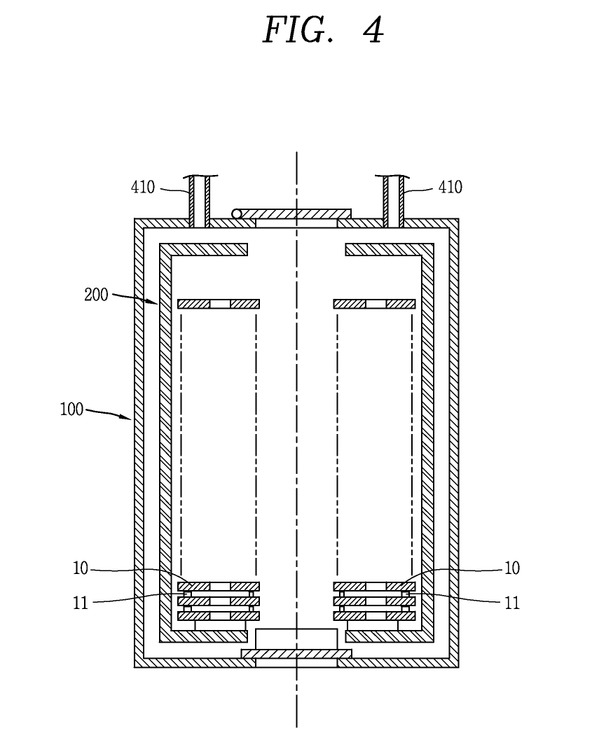

First, a large amount of preforms having the shape of a thin disc, such as a brake disc, is densified at a time, as illustrated in FIG. 4, the preforms 10 are vertically loaded into the reaction chamber 100, with the detachable heater 300 separated from the reaction chamber 100. When the preforms 10 are loaded, a spacer 11 is put in between the preforms 10 so that a gas can smoothly flow between the preforms 10. The preforms 10 are loaded in a plurality of columns. The preforms 10 are loaded into the reaction chamber 100, with the reaction chamber 100 open by opening the left door part 120 or the right door part 130.

After the large amount of preforms 10 are loaded in the reaction chamber 100, power is supplied to the fixed heater 200, with the reaction chamber 100 closed by closing the left door part 120 (or the right door part 130). As power is supplied to the fixed heater 200, the fixed heater 200 heats the inside of the reaction chamber 100 up to a predetermined temperature by generating heat. Then, a gas is injected into the reaction chamber 100 through the gas supply unit 40. In general, a preform is densified by applying heat treatment to the preform at about 1000° C. under an inactive atmosphere, increasing the content of carbon by thermally removing components (nitrogen, hydrogen, and oxygen) except for carbon, and then supplying a reaction gas at a temperature of 900 to 1000° C. under atmospheric pressure.

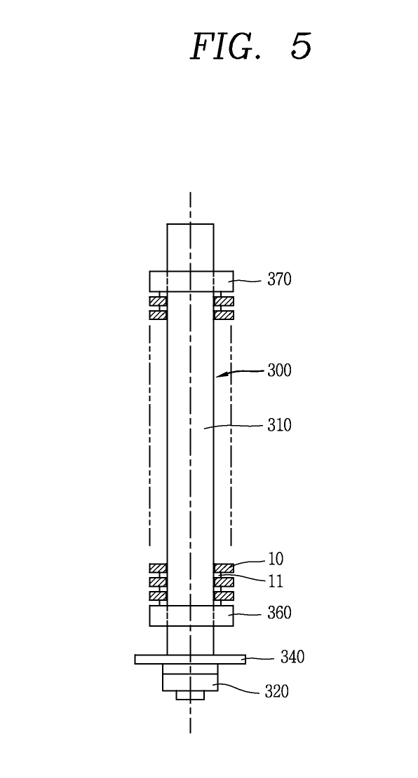

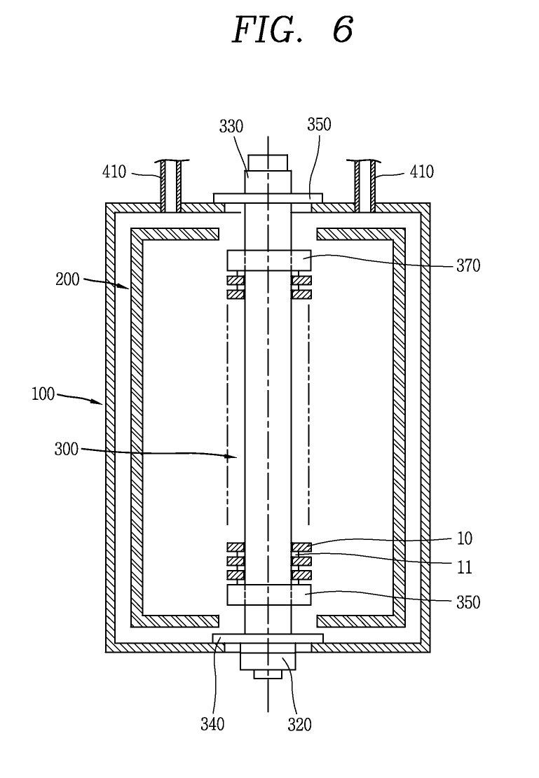

On the other hand, when a small amount of preforms are densified, with the detachable heater 300 separated from the reaction chamber 100, as illustrated in FIG. 5, the upper terminal 330, the upper coupler 350, and the upper support 370 of the detachable heater 300 are separated and the preforms 10 are fitted on the heating body 310, such that the preforms 10 are loaded in the heating body 310. Then, the loaded preforms 10 are supported by combining the upper support 370 with the heating body 310, and the upper terminal 330 and the upper coupler 350 are combined with the heating body 310. The detachable heater 300 loaded with the preforms 10 is combined with the reaction chamber 100, as illustrated in FIG. 6. The preforms 10 loaded on the heating body 310 of the detachable heater 300 is disposed in the reaction chamber 100, the lower coupler 340 is coupled to the bottom of the reaction chamber 100, and the upper coupler 350 is coupled to the top of the reaction chamber 100. Power is supplied to the detachable heater 300, with the reaction chamber 100 closed. As power is supplied to the detachable heater 300, the heating body 310 generates heat, and when the heating body 310 reaches a predetermined temperature, a gas is injected into the reaction chamber 100 through the gas supply unit 400. When the heating body 310 generates heat and the surface temperature of the heating body 310 reaches a deposition temperature or more, the heat transfers to the preforms 10 and heats them from the inside to the outside . Further, the gas injected in the reaction chamber 100 is decomposed from the inside of the preforms 10 and deposited from the inside to the outside of the preforms 10.

When a small amount of thick preforms are densified, the heat generated by the heating body 310 of the detachable heater 300 transfers directly to the preforms, such that the preforms are heated from the inside to the outside and the gas injected in the reaction chamber 100 is decomposed from the inside of the preforms and deposited from the inside to the outside of the preforms, thereby achieving uniform densifying the preforms.

A remaining gas after reaction in the preforms 10 is discharged to the outside of the reaction chamber 100 through the gas exhaust pipe 510.

As described above, according to the present invention, when there is many preforms to be densified, the preforms are loaded into the reaction chamber 100 with the detachable heater 300 separated and then the fixed heater 200 is operated, thereby densifying the preforms . Further, when there are a small number of preforms to be densified, the preforms are loaded on the detachable heater 300, the detachable heater is mounted in the reaction chamber, and then the detachable heater 300 is operated, thereby densifying the preforms. Accordingly, it is possible to a large amount of preforms and a small amount of preforms with one piece of equipment, and when a small number of preforms are densified, the preforms are densified by operating only the detachable heater 300, such that preforms are densified with a small amount of power energy, and accordingly, energy consumption is minimized.

Further, according to the present invention, when preforms are loaded on the detachable heater 300 and the preforms are densified by operating the detachable heater 300, the heat from the detachable heater 300 transfers directly to the preforms and heats the preforms from the inside to the outside and the gas is deposited from the inside to the outside of the preforms, such that the preforms are uniformly densified and the time taken to densify the preform is reduced.

While the present invention has been illustrated and described in connection with the exemplary embodiments, it will be apparent to those skilled in the art that modifications and variations can be made without departing from the spirit and scope of the invention as defined by the appended claims.

What is claimed is:

1. A densifying apparatus comprising:
a reaction chamber;
a fixed heater is disposed close to the inner wall of the reaction chamber and generating heat;
a detachable heater detachably coupled to the reaction chamber and generating heat; and
a gas supply unit supplying a gas into the reaction chamber.

2. The apparatus of claim 1, wherein the reaction chamber is formed in the shape of a cylinder having an internal space, with the top and the bottom closed, and is radially separated in to three parts, and
the three parts are a center body that is the middle part, a left door part hinged to a first side of the center body and opening/closing the first side of the center body, and a right door part hinged to a second side of the center body and opening/closing the other side of the center body.

3. The apparatus of claim 2, wherein contact plates having uniform width and thickness are disposed outside the edges of both opening sides of the center body, a contact plate facing one of the contact plates of the center body is disposed outside the edge of the left door part, and a contact plate facing the other contact plate of the center body is disposed outside the edge of the right door part.

4. The apparatus of claim 1, wherein the fixed heater includes a cylindrical heating unit disposed in the reaction chamber, an upper ring-shaped heating unit having a circular disc shape with the center bored and disposed on the top of the cylindrical heating unit, and a lower ring-shaped heating unit having a circular disc shape with the center bored and disposed under the cylindrical heating unit.

5. The apparatus of claim 1, wherein the detachable heater is attached/detached longitudinally vertically to/from the reaction chamber.

6. The apparatus of claim 1, wherein the detachable heater includes a heater body formed in the shape of a circular rod, a lower coupler disposed at the lower end of the heating body and attached/detached to/from the bottom of the reaction chamber, an upper coupler disposed at the upper end of the heating body and attached/detached to/from the top of the reaction chamber.

7. The apparatus of claim 6, wherein a lower support is formed at the lower portion of the heating body and supports a ring-shaped preform, and an upper support is formed at the upper portion of the heating body and supports a preform fitted on the heating body.

8. The apparatus of claim 7, wherein the lower support and the upper support are formed in the shape of a ring having uniform width and height.

9. The apparatus of claim 1, wherein doors that close the portions where the detachable heater is attached/detached when the detachable heater is separated are formed on the top and the bottom, respectively, of the reaction chamber.
